(19) United States
(12) Patent Application Publication
(10) Pub. No.: US 2026/0259578 A1
(43) Pub. Date: Sep. 3, 2026

(54) SIGNAL DISTRIBUTION CIRCUIT

(71) Applicant: Telefonaktiebolaget LM Ericsson (publ), Stockholm (SE)

(72) Inventors: Ufuk ÖZDEMIR, Lund (SE); Hind DAFALLAH, Lund (SE); Ghanashyam Ravindranath PRABHU, Linköping (SE)

(21) Appl. No.: 19/489,452

(22) PCT Filed: Jun. 9, 2023
(86) PCT No.: PCT/EP2023/065529

§ 371 Date: Dec. 2, 2025

(51) Int. Cl. G06F 1/10; H03F 1/08; H03F 1/26; H03F 3/45

(52) U.S. Cl. CPC G06F 1/10; H03F 1/083; H03F 1/26; H03F 3/45475

(57) ABSTRACT

In an example, a signal distribution circuit for distributing a clock signal or a local oscillator signal is provided. The signal distribution circuit includes a plurality of buffers connected between an input of the signal distribution circuit and an output of the signal distribution circuit. The signal distribution circuit also includes an amplifier circuit having an amplifier and a feedback resistance, wherein an input of the amplifier circuit is connected to an output of one of the buffers, and wherein the feedback resistance is connected between the input of the amplifier and an output of the amplifier.

### TECHNICAL FIELD

Example embodiments of this disclosure relate to signal distribution circuits, for example for distributing a clock signal or local oscillator signal.

### BACKGROUND

There are several major trends in wireless telecommunication technologies in recent decades that are shaping transceivers architectures. One of them is the increase of radio frequency (RF) carriers to higher and higher frequencies. There are 5G bands defined at around 40 GHz, and 6G is aiming for even higher frequencies. This is fuelled by increased bandwidth demands of consumers, and overcrowding of bands below 6 GHz. The enabling factors are advancements in beamforming and Phased Array Antenna Modules.

Since there are parallel transceivers in phased arrays, the performance of local oscillator (LO) distribution circuits (in terms of current consumption, noise and amplitude) have become more critical than before. Below 6 GHz, it is convenient to implement LO distribution circuits as cascaded inverters. Since pMOS and nMOS transistors are working in a complementary parallel configuration in such circuits, their gains add up increasing efficiency. They are straightforward to use, don't require inductors, and hence are small in terms of area and have no EM (electromagnetic) complications.

Inductors are very common in RF signal paths due to their efficiency and tuned characteristics which help to filter out unwanted components in the RF spectrum. However, they interact with each other due to EM coupling, and yield unexpected issues such as frequency shift due to mutual inductance, crosstalk, quality factor (Q) degradation, interference, and oscillations. Hence, inductors physically close to each other need to be modelled together, which complicates the design. Since the signal path of transceivers usually employ inductors, circuit designers try to avoid using additional inductors in the LO path.

Another major trend is the increasing sampling rates of data converters. With new architectures and combination techniques (like time-interleaving) and down scaling of complementary MOS processes, a new segment of transceivers has emerged called RF converters. These are data converters operating at radio frequencies, sampling the RF carrier directly, typically at clock ranges above 15 GHz. Since they are usually based on mixed signal design techniques, inverters are also preferred instead of inductor based tuned circuits in their clock distribution blocks.

Both of these above trends push the LOs and clock (CLK) signals in transceiver circuits to higher frequencies, and in both cases inductorless solutions are preferred.

Inverters are easy to implement, and have good efficiency, but may result in a major issue if used at high frequencies in LO/CLK Distribution chains for transceivers and data converters. The issue manifests itself as noise humps around the carrier at the output spectrum, especially at high carrier frequency and at high carrier power. The mechanism causing the noise humps is as follows:

Inverter chains are broadband circuits whose cut off frequencies are set by DC block capacitors at the low frequencies, and parasitic RC (resistor and capacitor) circuits at high frequencies. If DC-block capacitors are not considered, the chain inherently has a low-pass characteristic, having many RC poles. The dominant poles are, at each node, due to the RC network formed by the output impedance (rds) of a driving transistor and the input capacitance (Cgs) of load transistor. In addition, each routing in the distribution causes additional RC poles due to the parasitic resistances and capacitances of the metal tracks. These poles are at high frequencies, and each real pole lowers the frequency response by 3 dB at the pole frequency. However, they also cause a small roll-off at much lower frequencies. Therefore, many real poles each yielding a small roll-off add up to a significant droop even at low frequencies. As a result of this droop, for an LO/CLK distribution chain with many inverter-based buffers, the gain at low-end (e.g. 1 GHz) is much higher than the gain at the LO/CLK frequency, especially in small-signal operation.

Normally the chain operates in large signal mode due to LO/CLK, where the gain is compressed, and the issue may not be visible in simulations. However, it is quite probable that, due to unforeseen parasitics of the layout or inaccuracies of the models in the process design kit (PDK), the LO/CLK amplitude in the measurements might be smaller compared to simulations. This pushes the gain curve towards small-signal operation conditions, which starts to peak at low cut off frequency. The high gain at the low-end frequencies amplifies the thermal noise yielding a noise peak there. If many inverters are cascaded, the LO/CLK signal entering a mixer or sampler has a significant noise hump at the low-end frequency of its output spectrum.

Unfortunately, mixers and samplers are meant to operate non-linearly. They fold/alias the noise peak to both sides of the carrier. As a result, the noise peak at e.g. 1 GHz of LO/CLK becomes two noise peaks around the carrier, 1 GHz below and 1 GHz above it. For example, if we have an inverter based CLK chain operating at 16 GHz, it has gain from around 1 GHz up to 30-40 GHz depending on the layout parasitics and drive strength. There is a need for gain only at around 16 GHz and higher frequencies (to e.g. include 3rd harmonic to have steeper clock edges), but gain is achieved over a much broader bandwidth, starting from frequencies around 1 GHz.

The intuitive solution to the problem is to filter out the noise, which usually requires inductors, either to have complex poles in a high-pass filter or a band-pass filter. However, inductors come at the expense of increased die area and increased design complexity since they interact with each other and need to be modelled together in EM tools together.

### SUMMARY

Examples of this disclosure may have certain advantages. For example, examples of this disclosure can reduce LO/CLK jitter without using any inductors, and can be used either to improve the jitter performance of a good CLK and/or to mitigate noise humps, if they exist. Examples of this disclosure can easily be implemented in a switchable manner to be enabled only in the cases where it is needed, such as for example, when noise humps are present, at high temperatures, with SS samples, and/or when the carrier frequency and power are high.

One aspect of the present disclosure provides a signal distribution circuit for distributing a clock signal or a local oscillator signal. The signal distribution circuit comprises a plurality of buffers connected between an input of the signal distribution circuit and an output of the signal distribution circuit. The signal distribution circuit also comprises an amplifier circuit comprising an amplifier and a feedback resistance, wherein an input of the amplifier circuit is connected to an output of one of the buffers, and wherein the feedback resistance is connected between the input of the amplifier and an output of the amplifier.

Another aspect of the present disclosure provides a device comprising the signal distribution circuit of the above aspect, and a further circuit connected to an output of the signal distribution circuit.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 shows an example of a frequency distribution measured at the output of an analog to digital converter (ADC);

FIG. 2 shows an example of a simulation result of a frequency distribution of the output of an ADC;

FIG. 3 shows an example of a simulation result of gain curves for small signal and large signal operation of a clock distribution circuit;

FIG. 4 shows an example of a simulation result of the frequency distribution of the output of a clock distribution circuit;

FIG. 5 shows an example of the simulated properties of a transimpedance amplifier (TIA) with ideal components;

FIG. 6 shows an example of the simulated properties of a TIA;

FIG. 7 shows an example of signal distribution circuit for distributing a clock signal or a local oscillator signal according to this disclosure;

FIG. 8 shows an example of a simulation result of the frequency distribution of an ADC output signal;

FIG. 9 shows an example of a simulation result of a clock signal output from a clock distribution circuit;

FIG. 10 shows an example of a simulation result of a clock signal output from a clock distribution circuit according to this disclosure;

FIG. 11 shows an example of a simulation result of a clock signal output from a clock distribution circuit; and

FIG. 12 shows an example of a simulation result of a clock signal output from a clock distribution circuit according to this disclosure.

### DETAILED DESCRIPTION

The following sets forth specific details, such as particular embodiments or examples for purposes of explanation and not limitation. It will be appreciated by one skilled in the art that other examples may be employed apart from these specific details. In some instances, detailed descriptions of well-known methods, nodes, interfaces, circuits, and devices are omitted so as not obscure the description with unnecessary detail.

Embodiments of this disclosure provide a signal distribution circuit for distributing a signal such as a clock signal or a local oscillator signal. Example circuits include a noise trap (NT) in the LO/CLK distribution chain, for example at the end of the chain, which will suppress low frequency noise before entering another component such as a mixer or sampler. The noise trap can be an amplifier circuit, for example a TIA (trans impedance amplifier) presenting a low impedance at frequencies where the noise peaks.

Harmonic traps are widely used to remove specific components in the spectrum, such as for example 3rd RF harmonic, 5th LO harmonic etc. TIAs are commonly used as base-band amplifiers in transceivers, due to their low input impedance, to convert a current to a voltage, e.g. at the output of current mode mixers. They are even necessary components in wire-line circuits, converting output currents of photodiodes to voltage.

In some examples, noise trap operates from DC up to operation bandwidth of the amplifier circuit or TIA. It suppresses noise within the bandwidth of the amplifier circuit without affecting the LO/CLK amplitude significantly.

TIAs present very low impedance at their input, called “virtual ground”, within their operating bandwidth. Hence, in some examples, if connected as a shunt element to a node in the LO/CLK path, they will convey the noise power within their bandwidth to ground. Since their input impedance increases at high frequencies (becomes the value of a feedback resistance Rfbk, when their gain diminishes), the LO/CLK amplitude is not significantly affected by the presence of the amplifier circuit.

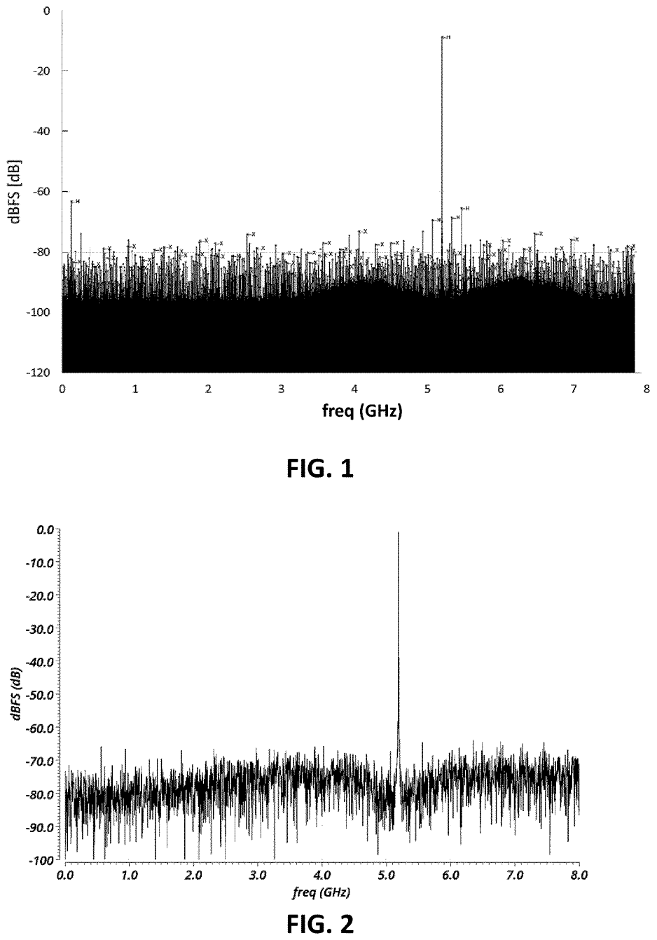

FIG. 1 shows an example of a frequency distribution measured at the output of an analog to digital converter (ADC). Input to the ADC is a RF signal at around 5.3 GHz from a signal generator, which is low noise. The humps arise due to the clock noise. The noise humps are clearly visible around the carrier at around +/−1 GHz offset. The power of the humps increases with frequency and power of the carrier. FIG. 2 shows an example of a simulation result of a frequency distribution of the output of an ADC. This shows that the issue can be reproduced in a simulator, where extra parasitics, in the form of additional resistors in the power supplies and capacitive loads in the clock path, are added to the clock/LO distribution chain. Again, noise humps can be seen at around +/−1 GHz offset from the carrier frequency of around 5.3 GHz.

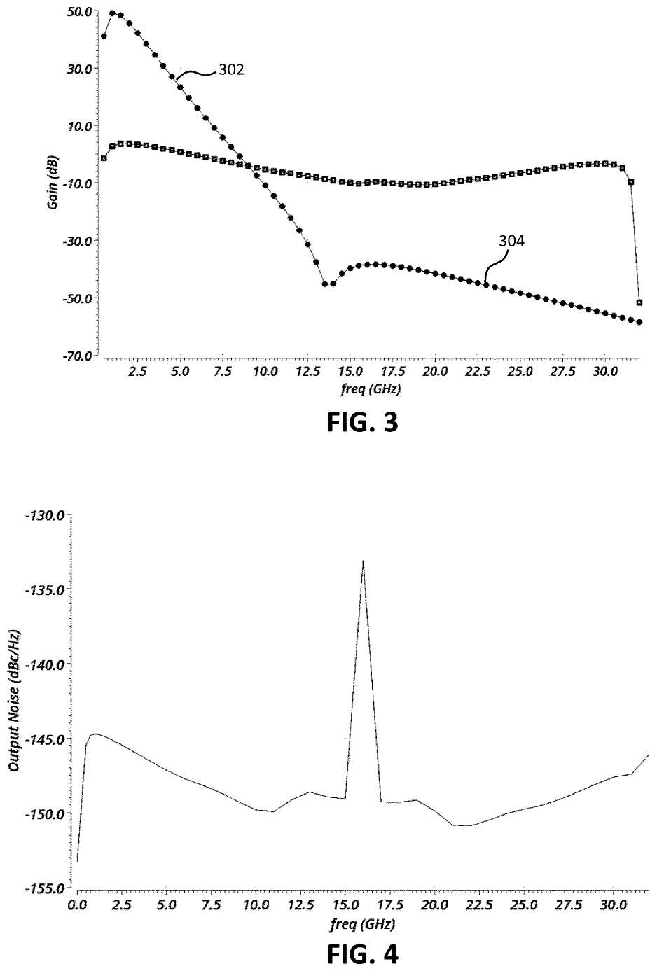

The mechanism which causes the issue can be explained in several steps. FIG. 3 shows an example of a simulation result of gain curves for small signal and large signal operation of a clock distribution circuit.

The first one is shown in FIG. 3, where gain of the CLK distribution over frequency is shown for two cases. The small signal gain curve 302 has a very high peak at around 1 GHz, which rolls off quickly at higher frequencies. The large signal gain curve 304 is flatter since, due to large CLK amplitude, the circuit is in gain compression. If the CLK amplitude in a real circuit is lower than simulated, which might be due to unforeseen parasitics (in the real circuit or in the models), the large signal gain curve 304 will be shifted towards the small signal gain curve 302, ending up somewhere between the two. The amount of shift depends on the amount of parasitics that are missing from the simulated circuit. Hence, there is a significant gain peak at ca 1 GHz.

FIG. 4 shows an example of a simulation result of the frequency distribution of the output of a clock distribution circuit, when the clock amplitude is realistic, i.e. when gain is somewhere between gain curves 302 and 304 shown in FIG. 3. The gain peak, which was shown in FIG. 3, amplifies the noise floor, and hence at the output of the clock distribution circuit the clock signal has a noise peak at around 1 GHz. When the LO/CLK signal enters a mixer or a sampler, in some examples, its noise is folded/aliased around the carrier frequency at the output of the mixer or sampler. The resulting spectrum has noise humps around the carrier, as shown in FIGS. 1 and 2.

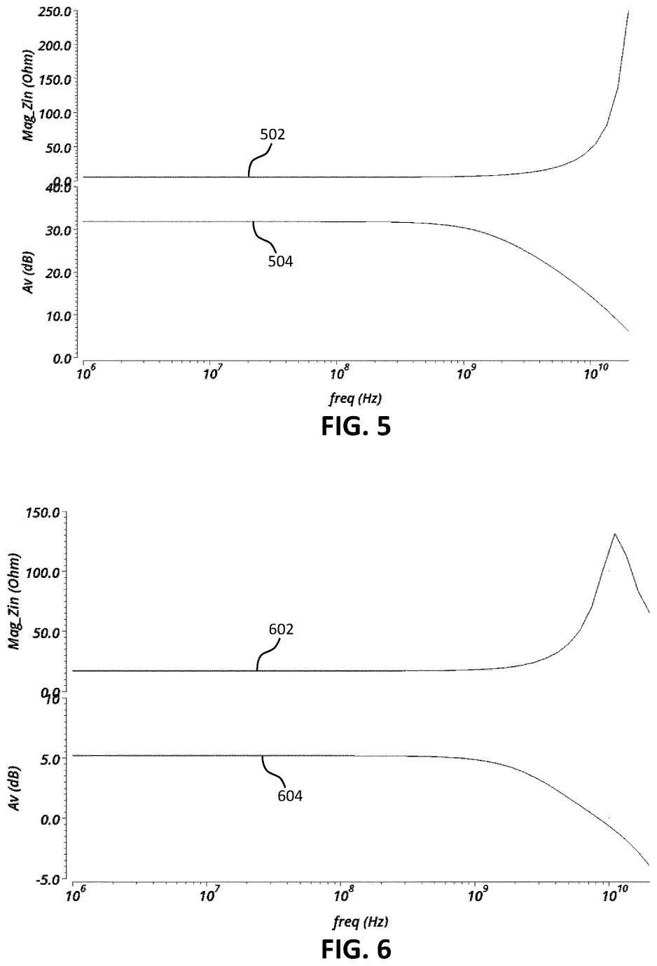

FIG. 5 shows an example of the simulated properties of a transimpedance amplifier (TIA) with ideal components. As explained above, in some examples, a TIA is connected to the output of one of the buffers in a signal distribution circuit as a noise trap at the end of the buffer chain to suppress the noise before it enters another component such as a mixer or sampler. The input impedance 502 of the simulated TIA is low within its bandwidth and increases at higher frequencies when its gain 504 diminishes, as shown in FIG. 5 and equation below:

$$Zin ( s ) = \frac{Rfbk}{( 1 + Av ( s ) )}$$

$$For Av ( s ) = ∞ , Zin \to 0 ;$$

$$Av ( s ) = 0 , Zin = Rfbk$$

Using the TIA with ideal components in a signal distribution circuit according to this disclosure showed promising results when simulated. It improved CLK jitter, flattened noise humps and increased the effective number of bits (ENOB).

The TIA was then implemented in an example of a signal distribution circuit. The example inverter-based TIA used consumes 4.5 mA and has the input impedance (Zin) 602 and gain (Av) 604 characteristics as shown in FIG. 6, which shows an example of a simulation of the properties of the transimpedance amplifier (TIA). It presents 18 Ohm at 1 GHz, and 87 Ohm at 16 GHz. This example TIA is simulated using transistor models from a design kit, hence shows expected performance of produced silicon. It consumes current and has realistic character in terms of noise, input capacitance and nonlinearity. Input impedance Zin drops off at high frequencies due to input capacitance, i.e. Cgs of input transistors.

Besides the feedback resistance Rfbk, the example TIA consists of three self-biased inverter stages, whose drive strength (width) is increasing at each stage. There is an RC network at the input which is needed to protect the transistors from the large CLK amplitude so that the TIA always stays in small signal operation. The capacitance at the output also forms an RC network with the feedback resistance Rfbk for the same purpose. Additionally, they limit the bandwidth so that the gain diminishes at CLK frequencies.

The TIA was developed to test the concept of the signal distribution circuits of this disclosure, and hence in other examples an alternative TIA or amplifier circuit may be used. The target for the TIA was to keep its current consumption below 5 mA. Its stability was checked in large signal conditions using harmonic balance stability analysis.

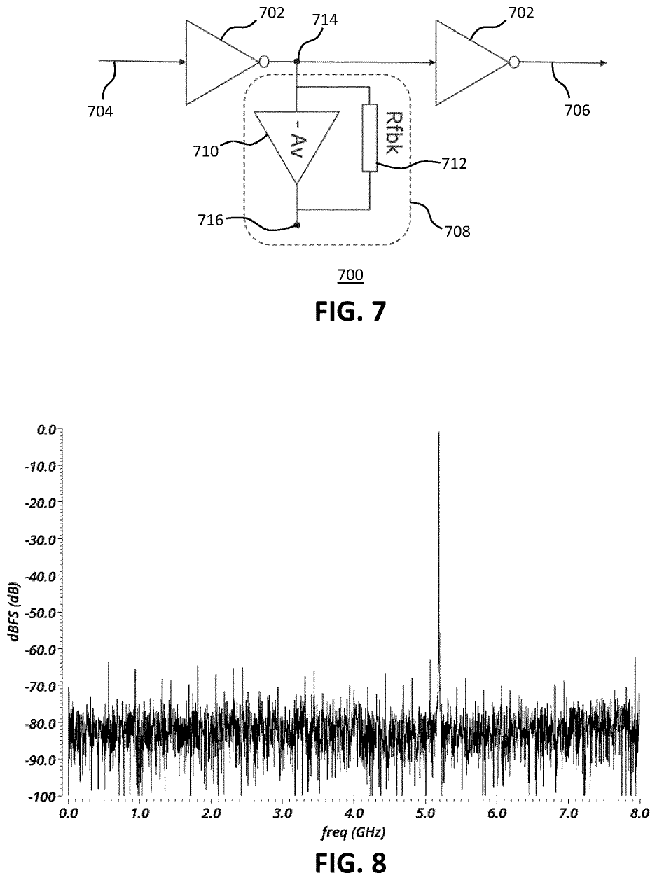

FIG. 7 shows an example of signal distribution circuit 700 for distributing a clock signal or a local oscillator signal according to this disclosure. The signal distribution circuit 700 comprises a plurality of buffers 702 connected in series between an input 704 of the signal distribution circuit and an output 706 of the signal distribution circuit 700. The signal distribution circuit 700 also includes an amplifier circuit 708. The amplifier circuit 708 comprises an amplifier 710 and a feedback resistance 712 (e.g. a resistor). An input of the amplifier circuit (e.g. a input of the amplifier 710) is connected to an output 714 of one of the buffers, and the feedback resistance 712 (with resistance value Rfbk) is connected between the input of the amplifier 714 and an output 716 of the amplifier 710. Thus, in the example circuit 700 shown in FIG. 7, the amplifier circuit 708 is a transimpedance amplifier (TIA).

In the example shown, the buffers 702 are two inverters, and the input of the amplifier circuit 708 is connected to a node 714 between the inverters. However, in other examples, there may be any number of buffers which may be inverters (or inverting buffers) or non-inverting buffers, and the input of the amplifier circuit 708 is connected to the output of any of the buffers 702. For example, the input of the amplifier circuit 708 may be connected to the output of the last buffer, and thus is also connected to the output 706 of the signal distribution circuit 700 in this example.

In some examples, the amplifier 710 comprises an inverting amplifier. For example, the amplifier 710 comprises a differential amplifier or an operational amplifier, and the input of the amplifier circuit 708 is connected to an inverting input of the amplifier 710. A non-inverting input of the amplifier 710 may be connected to a reference voltage such as ground for example.

The output of the amplifier circuit 708 may be unused in some examples. For example, the output of the output of the amplifier 710 may be connected only to the feedback resistance 712, and to no other components. Alternatively, for example, the output of the amplifier 710 may be connected via one or more passive components to a reference voltage (e.g. rgound) or an open circuit.

In some examples, the input impedance of the amplifier circuit 708 (and the amplifier 710) may be higher for a higher frequency, such as for example shown in FIGS. 5 and 6. Additionally or alternatively, in some examples, the input impedance of the amplifier is lower for a lower frequency, such as for example shown in FIGS. 5 and 6. In other words, in some examples, the input impedance of the amplifier is a first input impedance for a first frequency range and a second input impedance for a second frequency range, wherein the first frequency range is lower than the second frequency range and the first input impedance is lower than the second input impedance.

Similarly, in some examples, the gain of the amplifier circuit 708 (and the amplifier 710) is lower for a higher frequency, such as for example shown in FIGS. 5 and 6. Additionally or alternatively, in some examples, the gain of the amplifier is higher for a lower frequency, such as for example shown in FIGS. 5 and 6. In other words, in some examples, the gain of the amplifier is a first gain for a first frequency range and a second gain for a second frequency range, wherein the first frequency range is lower than the second frequency range and the first gain is higher than the second gain.

In some examples, the output 706 of the signal distribution circuit 700 (or any signal distribution circuit according to this disclosure) may be connected to a further circuit, such as for example a mixer, sampler or processor. The signal distribution circuit may thus be configured to provide a clock signal or a local oscillator signal to the further circuit.

FIG. 8 shows an example of a simulation result of the frequency distribution of an ADC output signal, where the input to the ADC is a clock signal provided by a signal distribution circuit according to this disclosure. Specifically, the same simulated clock distribution circuit and ADC used to produce the simulation result of FIG. 2 was used, with the addition of a TIA such as for example shown in FIG. 7. It can be seen that the noise humps evident in FIG. 2 have been reduced or even eliminated entirely in FIG. 8. For example, the integrated noise has been reduced by around 3.5 dB, increasing ENOB of the ADC by around half a bit.

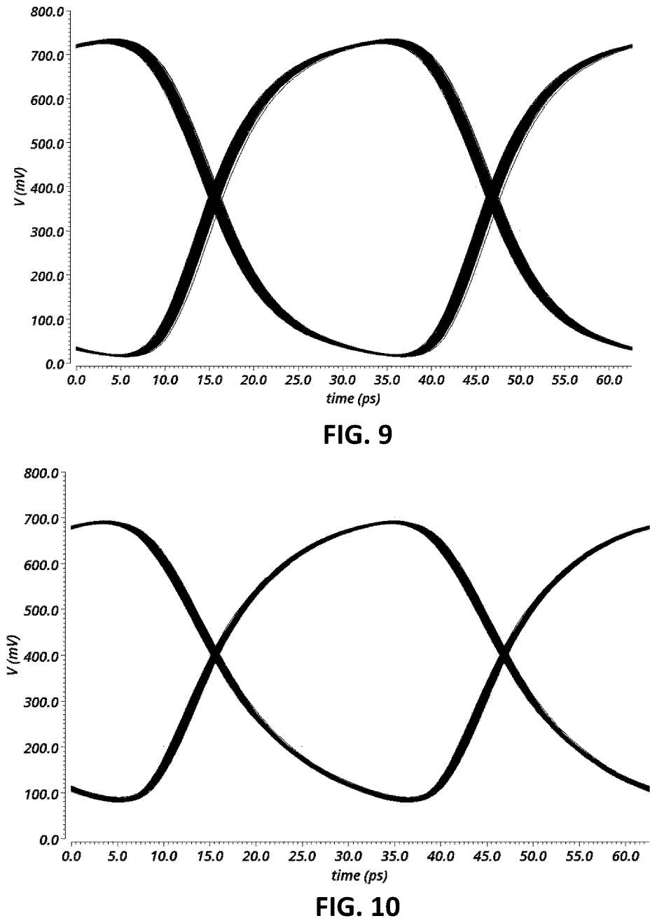

Signal distribution circuits according to this disclosure may also provide improvements in clock jitter. FIG. 9 shows an example of a simulation result of a clock signal output from a clock distribution circuit. The peak-to-peak jitter for the clock signal output was 1.62 ps. FIG. 10 shows an example of a simulation result of a clock signal output from a clock distribution circuit according to this disclosure, including an amplifier circuit such as the amplifier circuit 708 shown in FIG. 7. This shows that the clock jitter reduced to 0.92 ps.

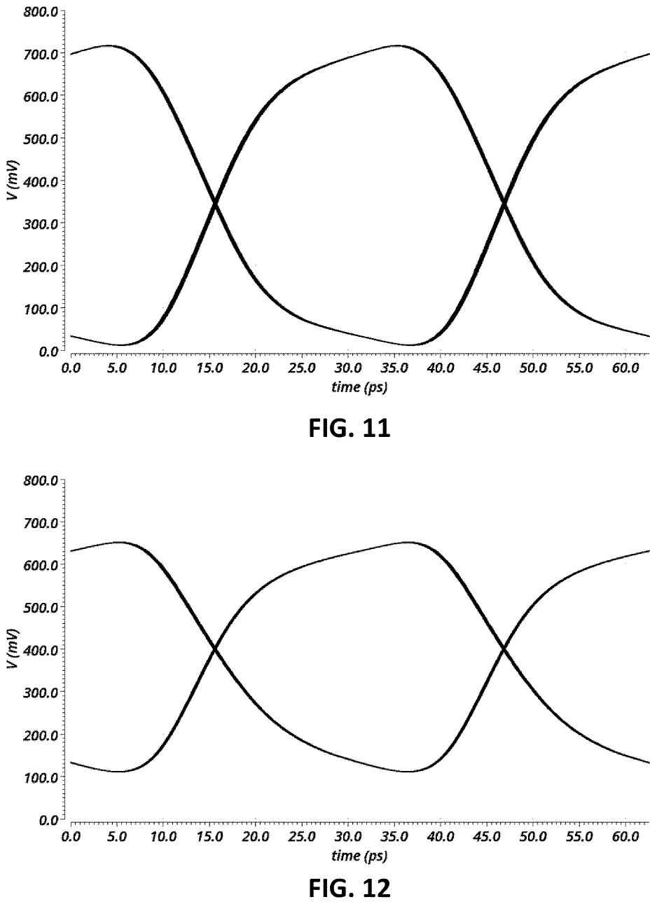

Example circuits of this disclosure may also improve clock jitter where the jitter is already good. FIG. 11 shows an example of a simulation result of a clock signal output from a clock distribution circuit, and FIG. 12 shows an example of a simulation result of a clock signal output from a clock distribution circuit according to this disclosure, including an amplifier circuit such as the amplifier circuit 708 shown in FIG. 7. It is shown that clock jitter was reduced from 432 fs in FIG. 11 to 289 fs in FIG. 12. RMS jitter was improved from 70 fs to 50 fs. The integrated noise was reduced only by 1 dB, since the CLK jitter was already low, and it was not dominating the total noise. This evaluation shows that signal distribution circuits according to this disclosure can be used not only to mitigate noise humps, but also to improve performance.

It should be noted that the above-mentioned examples illustrate rather than limit the invention, and that those skilled in the art will be able to design many alternative examples without departing from the scope of the appended statements. The word “comprising” does not exclude the presence of elements or steps other than those listed in a claim, “a” or “an” does not exclude a plurality, and a single processor or other unit may fulfil the functions of several units recited in the statements below. Where the terms, “first”, “second” etc. are used they are to be understood merely as labels for the convenient identification of a particular feature. In particular, they are not to be interpreted as describing the first or the second feature of a plurality of such features (i.e., the first or second of such features to occur in time or space) unless explicitly stated otherwise. Steps in the methods disclosed herein may be carried out in any order unless expressly otherwise stated. Any reference signs in the statements shall not be construed so as to limit their scope.

1. A signal distribution circuit for distributing a clock signal or a local oscillator signal, the signal distribution circuit comprising:
a plurality of buffers connected between an input of the signal distribution circuit and an output q of the signal distribution circuit; and
an amplifier circuit comprising an amplifier/and a feedback resistance, an input of the amplifier circuit being connected to an output of one of the buffers, and the feedback resistance being connected between the input of the amplifier and an output of the amplifier.

2. The signal distribution circuit of claim 1, wherein each of one or more of the buffers q comprises an inverting buffer or an inverter.

3. The signal distribution circuit of claim 1, wherein the input of the amplifier circuit is connected to the output of the signal distribution circuit.

4. The signal distribution circuit of claim 1, wherein the amplifier comprises an inverting amplifier.

5. The signal distribution circuit of claim 1, wherein the amplifier comprises a differential amplifier or an operational amplifier.

6. The signal distribution circuit of claim 5, wherein the input of the amplifier circuit is connected to an inverting input of the amplifier.

7. The signal distribution circuit of claim 5, wherein a non-inverting input of the amplifier is connected to a reference voltage or ground.

8. The signal distribution circuit of claim 1, wherein:
the output of the amplifier is connected only to the feedback resistance;
an output signal of the amplifier is unused; or
the output of the amplifier is connected via one or more passive components to a reference voltage or an open circuit.

9. The signal distribution circuit of claim 1, wherein the amplifier circuit comprises a transimpedance amplifier.

10. The signal distribution circuit of claim 1, wherein the input of the amplifier is connected to the output of the signal distribution circuit.

11. The signal distribution circuit of claim 1, wherein one or more of:
an input impedance of the amplifier circuit is higher for a higher frequency;
the input impedance of the amplifier circuit is lower for a lower frequency; and
the input impedance of the amplifier circuit is a first input impedance for a first frequency range and a second input impedance for a second frequency range, wherein the first frequency range is lower than the second frequency range and the first input impedance is lower than the second input impedance.

12. The signal distribution circuit of claim 1, wherein one or more of:
a gain of the amplifier circuit is lower for a higher frequency;
the gain of the amplifier circuit is higher for a lower frequency; and
the gain of the amplifier circuit is a first gain for a first frequency range and a second gain for a second frequency range, wherein the first frequency range is lower than the second frequency range and the first gain is higher than the second gain.

13. A device comprising:
a signal distribution circuit for distributing a clock signal or a local oscillator signal, the signal distribution circuit comprising:
a plurality of buffers connected between an input of the signal distribution circuit and an output of the signal distribution circuit; and
an amplifier circuit comprising an amplifier and a feedback resistance, an input of the amplifier circuit being connected to an output of one of the buffers, and the feedback resistance being connected between the input of the amplifier and an output of the amplifier; and
a further circuit connected to the output of the signal distribution circuit.

14. The device of claim 13, wherein the signal distribution circuit is configured to provide a clock signal or a local oscillator signal to the further circuit.

15. The device of claim 13, wherein the further circuit comprises a mixer, sampler or processor.

16. The signal distribution circuit of claim 2, wherein the input of the amplifier circuit is connected to the output of the signal distribution circuit.

17. The signal distribution circuit of claim 2, wherein the amplifier comprises an inverting amplifier.

18. The signal distribution circuit of claim 2, wherein the amplifier comprises a differential amplifier or an operational amplifier.

19. The signal distribution circuit of claim 18, wherein the input of the amplifier circuit is connected to an inverting input of the amplifier.

20. The signal distribution circuit of claim 18, wherein a non-inverting input of the amplifier is connected to a reference voltage or ground.
